(19) United States
(12) Patent Application Publication
(10) Pub. No.: US 2008/0180133 A1
(43) Pub. Date: Jul. 31, 2008

(54) Expandable decoding circuit and decoding method

(76) Inventors: Wen-Chi Hsu, Lugang Township (TW); Shu-Hua Kuo, Hsinchu City (TW); Jia-Jou Tsai, Taipei City (TW); Yu-Kuang Wu, Jhongli City (TW); Zhi-Wei Yang, Tainan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/698,831

(22) Filed: Jan. 29, 2007

(51) Int. Cl. H03K 19/00; G11C 8/10

(52) U.S. Cl. 326/105

(57) ABSTRACT

An expandable decoding circuit includes a latch unit, a latch result selecting unit, and at least one decoding circuit. The latch unit latches raw data and outputs the latch values and the latch inverse-values of the raw data. The latch result selecting unit composes the latch values and the latch inverse-values according to the target decoding value of the decoding unit to generate a pre-decoding value. The latch result selecting unit outputs the pre-decoding value to the corresponding decoding unit. The decoding circuit determines whether a decoding signal is outputted or not according to the pre-decoding value. Thereby, when a new function needs to be added to the deciding circuit, the present invention does not change the original decoding circuit and implements the decoding unit for the new function.

### BACKGROUND OF THE INVENTION

1. Field of the Invention

The present invention relates to a decoding circuit. In particular, this invention relates to an expandable decoding circuit having a new function.

2. Description of the Related Art

In the design of ICs, the quantity of logic gates used for decoding a large number of decoding processes is reduced as much as possible. Therefore, the size of the IC is reduced, and power consumption is lowered. There is now a trend to integrate ICs into a system. A variety of functions are integrated into a single chip. When this is done, the input/output data required for each of the functional units or the data transmitted between different functional units has to be decoded in advance. After the data has been decoded, the control signal or the data can be transmitted between the functional units.

Decoding circuits are popular in circuit application. The organization producing standard cell library usually provides n to 2ⁿ decoders to the user. However, because the application becomes complex day after day, the data processed by the system or device and the control logic also becomes complex. Therefore, if the user merely uses n to 2ⁿ decoders to deal with the decoding process, the dimensions of the circuit become large, and a large amount of power is required.

In order to solve the described problems, an optimization technology is adopted to obtain an optimization decoding circuit. However, when the optimization decoding circuit needs to be slightly modified or have one or two decoding sets added, the circuit needs to be re-designed. It is time consuming and the time to market for the electronic product is delayed.

### SUMMARY OF THE INVENTION

One particular aspect of the present invention is to provide an expandable decoding circuit in which the decoding circuit can be flexibly modified. The expandable decoding circuit includes a pre-processing circuit for the input data and a detecting function for detecting whether the input data meets the decoding conditions or not. When the circuit has been finished and an additional function needs to be added, the decoding circuit of the present invention adds the new function while the original circuit is not changed. In other words, when the decoding circuit needs to be slightly modified, the entire functions can be implemented at little cost and with only minor modifications.

The present invention provides an expandable decoding circuit. The expandable decoding circuit includes a latch unit, a latch result selecting unit, and at least one decoding circuit. The latch unit receives raw data and outputs latch values and latch inverse-values of the raw data to the latch result selecting unit. The latch result selecting unit receives the latch values and the latch inverse-values, and composes the latch values and the latch inverse-values according to the target decoding value of the decoding unit to output a pre-decoding value. The decoding circuit receives the pre-decoding value and determines whether the pre-decoding value meets the decoding conditions of the decoding circuit or not to decide whether a decoding signal is outputted or not.

The present invention also provides a decoding method. Firstly, raw data is received. Next, the latch value and the latch inverse-value of the raw data are generated. The latch values and the latch inverse-values compose a pre-decoding value according to a target decoding value of at least one decoding circuit. The pre-decoding value is outputted to the decoding circuit. Finally, the decoding circuit determines whether the pre-decoding value can be decoded or not. If the pre-decoding value can be decoded, the decoding circuit outputs a decoding signal.

Thereby, when a new function needs to be added to the deciding circuit, the present invention does not change the original decoding circuit and implements the decoding unit for the new function. The time required for the design is greatly reduced.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide a further understanding of the invention. A brief introduction of the drawings is as follows:

FIG. 1 is a schematic diagram of a structure of the decoding circuit of the present invention;

FIG. 2 is a detailed structural diagram of the pre-processing unit of the present invention;

FIG. 3 is a detailed structural diagram of the latch result selecting unit of the present invention;

FIG. 4 is a detailed structural diagram of the decoding unit of the preferred embodiment of the present invention; and

FIG. 5 is a detailed structural diagram of the decoding unit of another preferred embodiment of the present invention.

### DETAILED DESCRIPTION OF THE PREFERRED EMBODIMENTS

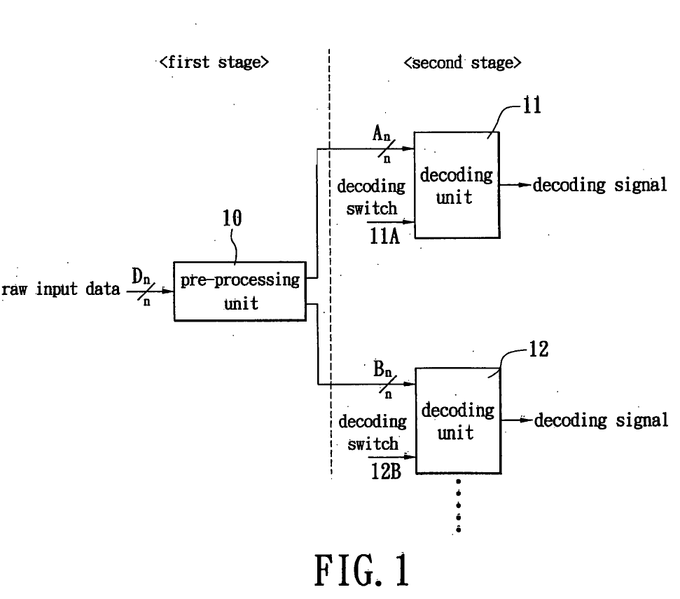

The present invention provides an operating structure for a decoder. FIG. 1 shows a schematic diagram of a structure of the decoding circuit of the present invention. Firstly, the decoding process for the raw input data Dₙ is illustrated. The decoding process can be divided into two stages. The first stage is the pre-decoding of the data by the pre-processing unit 10. In this stage, the raw input data Dₙ is stored in the latch unit. After the forward logic and the backward logic of the data are obtained, the pre-processing unit 10 selects proper signals, and composes and outputs to each of the decoding units 11, 12, and others according to the decoding requirements in the system. At the second stage, the decoding units 11, 12, (and other decoding units if necessary) decode the pre-decoding value obtained at the first stage. This means that a logically decoding judge is executed to determine whether the pre-decoding value meets the decoding conditions of the decoding unit or not so as to output a decoding signal.

Reference is made to FIG. 1. In this decoding circuit system, one pre-processing unit is required. The reason for this is that the raw input data Dₙ is stored by one latch unit. The data does not need to be duplicated into a large number of copies. The pre-decoding function of the pre-processing unit 10 composes and outputs the forward and backward output values of the latch unit, such as Aₙ and Bₙ. Therefore, the functions of the pre-processing unit 10 include storing the data and pre-decoding the data.

The decoding units 11, 12, . . . , etc are allocated according to the decoding unit required by the functional units (not shown in the figure). Therefore, when a variety of functional units exist in the system, the same number of decoding units is required. As shown in FIG. 1, the pre-processing unit 10 pre-decodes two sets of pre-decoding values, including Aₙ and Bₙ, and individually outputs to the decoding unit 11 and the decoding unit 12. The content of the two sets of pre-decoding values Aₙ and Bₙ is determined by the resource allocation of the functional units allocated by the system. The allocation resource includes a memory address, or an ID number, etc.

When the decoding unit 11 obtains the pre-decoding value Aₙ, the decoding unit 11 can use the few logic gates to decode the data because the decoding value has been pre-processed by the pre-processing unit 10. At the same time, the same decoding unit circuit can be used in different functional units. Therefore, the complexity of the IC design and the dimension of the IC are greatly reduced. Because the decoding and composing process are executed by the pre-processing unit 10, the selected and composing process can be increased or decreased by increasing or decreasing the decoding units 11, 12. The decoding and composing process are unchanged. This means that a new functional unit can be added to the system and the originally designed circuit is unchanged.

The decoding switches 11A, 12B located at the decoding units 11, 12 determine whether each of the decoding units 11, 12 is turned on or not. Furthermore, the decoding switches 11A, 12B can control the decoding units 11, 12 and lower power consumption.

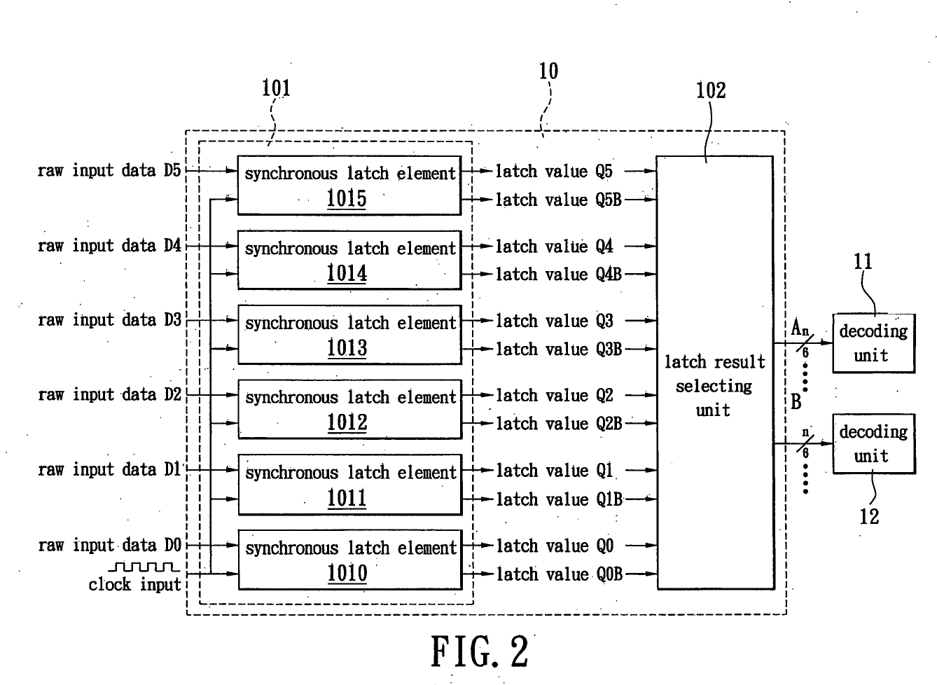

Reference is made to FIG. 2, which shows a detailed structural diagram of the pre-processing unit of the present invention. Firstly, the raw input data Dₙ is latched by the latch unit 101. Next, the latch result selecting unit 102 deals with the proper latch value and outputs to the decoding units 11, 12, . . . , etc. The processing unit 10 in FIG.2 is used as an example. The input data has 6 bits (D0˜D5). 6 synchronous latch elements 1010, 1011, 1012, 1013, 1014, and 1015 are used for latching the data. After the data is latched by the latch elements 1010, 1011, 1012, 1013, 1014, 1015, the latching value Q and the latching inverse-value QB are generated according to the characteristics of the latch elements. The Q0˜Q5 (the latch values) and the Q0B˜Q5B (the latching inverse-values) in FIG. 2 are the forward and backward latch values of the 6 latch elements.

Next, the latch result selecting unit 102 composes and outputs the latch values according to the characteristic value of the decoding target. If the target decoding value of the decoding unit 11 is 2A\H, the latch result selecting unit 102 inversely outputs the bits with 0 of 2A\H in binary. The 2A\H is 101010\B. the output Aₙ of the latch result selecting unit 102 is composed of the {Q5, Q4B, Q3, Q2B, Q1, Q0B} and outputs the composed value. The merit is that the forward logic is checked at the next decoding stage (checking whether Aₙ is 11111\B), and is unaffected by the target decoding value. If the target decoding value of the decoding unit 12 is 14\H, the output Bₘ of the latch result selecting unit 102 is composed of the {Q5B, Q4, Q3B, Q2, Q1B, Q0B} and the composed value is output because the 14\H is 010100\B.

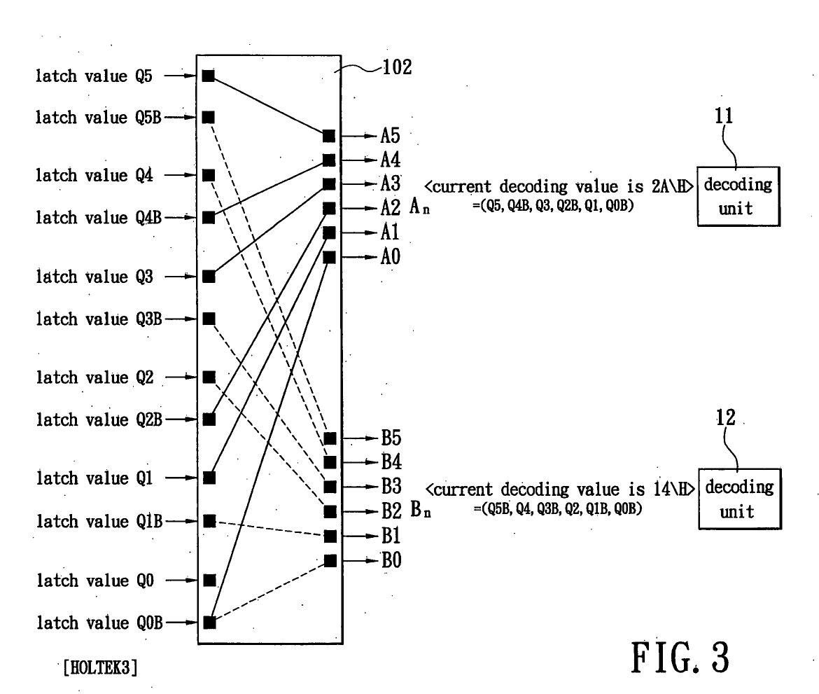

Reference is made to FIG. 3, which shows a detailed structural diagram of the latch result selecting unit of the present invention. When the target decoding value of the decoding unit 11 is 2A\H and the target decoding value of the decoding unit 12 is 14\H is used as an example, the detailed structural diagram of the latch result selecting unit 102 is illustrated. The latch result selecting unit 102 composes and outputs the latch result according to the characteristic value of the decoding target. Because there are a plurality of decoding units 11, 12, included in the system for individually charging the different target decoding values (in this diagram, the decoding units 11, 12 are used as an example), the latch result selecting unit 102 has to output the corresponding pre-decoding values Aₙ and Bₙ to the decoding units 11, 12. In the circuit implementation, the decoding circuit of the present invention adopts a linking and corresponding method to compose and output the latch values. Furthermore, when the decoding and composing circuit needs to be changed, the linking wires to the decoding units 11, 12 are merely increased or decreased. The finished system circuit is not affected.

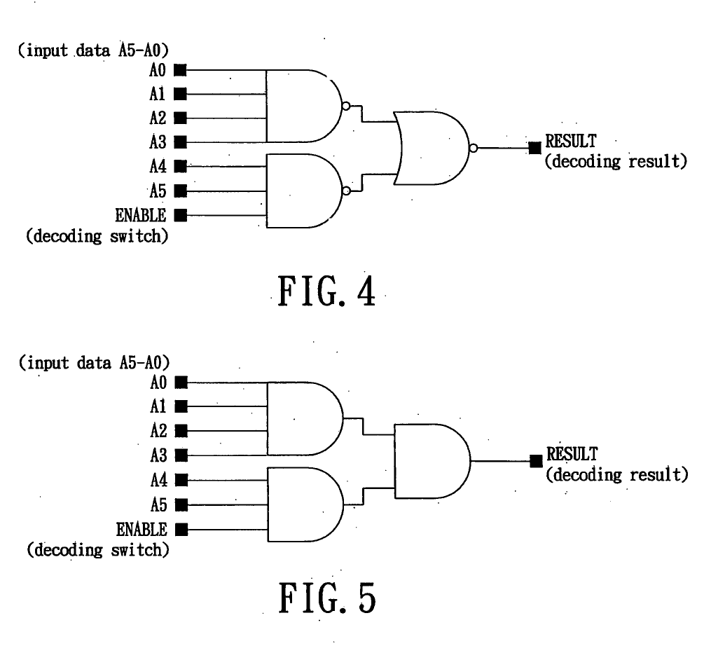

Because the function of the decoding units 11, 12 is to check whether the pre-decoding values from the pre-processing unit 10 are all equal to 1, the decoding units 11, 12 are designed by a logic circuit, referring to FIG. 4. The decoding unit uses two NAND gates to receive the pre-decoding value and the starting signal of the decoding switch. Next, the decoding unit uses an NOR gate to receive the output of the two NAND gates to determine whether the pre-decoding value meets the target value of the decoding unit or whether the decoding unit is turned off. For example, when the input data has 6 bits (A0˜A5) and all of the A0˜A5 are equal to 1, this means the pre-decoding value meets the target value of the decoding unit. At this time, whether the decoding switch receives the starting signal (is equal to 1) is checked to determine if the decoding unit is turned on. If the decoding unit is turned on, the decoding result (i.e. 1) is outputted. Except for a condition as described above, the decoding results are 0. This means the pre-decoding value does not meet the target value of the decoding unit or the decoding unit is turned off.

Reference is made to FIG. 5, which shows a structural diagram of the decoding unit of another preferred embodiment of the present invention. The decoding unit is composed of three AND gates. The decoding unit uses two AND gates to receive the pre-decoding value and the starting signal of the decoding switch. Next, the decoding unit uses another AND gate to receive the output of the two AND gate to determine whether the pre-decoding value meets the target value of the decoding unit or whether the decoding unit is turned off. The decoding circuit of the present invention is not limited to the types described above and/or the linking method of the logic elements. It mainly checks whether all of the pre-decoding values are equal to 1 and whether the status of the decoding unit is turned on or off.

From the illustration of the pre-processing unit 10, all of the signal wires are 1 if the pre-decoding value meets the decoding condition. Therefore, the operation of all of the decoding units of the functional units is the same as each other. The target is to check whether all of the pre-decoding values are equal to 1. Therefore, the circuit for each of the decoding units is the same as each other, and can be commonly used. Via the design, the present invention uses the few logic gates to implement the decoding unit, and the decoding unit can be commonly used in different functional units. Thereby, the design efficiency is increased and the error rate for the circuit design is lowered.

Moreover, after the latch result selecting unit 102 converts the pre-decoding value, the pre-decoding value can be transmitted to the decoding units 11, 12 of the second stage via two transmitting methods. The first method is that the latch result selecting unit 102 simultaneously outputs Aₙ, Bₙ to the corresponding decoding units 11, 12. Next, the decoding units 11, 12 checks whether Aₙ, Bₙ are equal to 1 or not. If Aₙ, Bₙ are equal to 1, this means the decoding process is finished. For example, when the raw input data Dₙ is 101010, the Aₙ outputted from the latch result selecting unit 102 is composed of {Q5, Q4B, Q3, Q2B, Q1, Q0B}. Therefore, the Aₙ is 111111, and is transmitted to the decoding unit 11 so that the decoding unit 11 operates. Bₙ is composed of {Q5B, Q4, Q3B, Q2, Q1B, Q0B}. Bₙ is 000001, and is transmitted to the decoding unit 12. The decoding unit 12 doesn't operate because all bits of Bₙ are not equal to 1. It is simple to implement this circuit.

The second method is that the first method cooperates with the system in turning off the non-relative decoding units via the decoding switches 11A, 11B. By this method, the system resource can be fully utilized and power consumption is reduced.

When the circuit has been finished and an additional function needs to be increased, the decoding circuit of the present invention can increase the functions while the original circuit is not changed. Therefore, the required design period is substantially reduced.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. An expandable decoding circuit, comprising:
a latch unit receiving raw data and outputting latch values and latch inverse-values of the raw data;
a latch result selecting unit receiving the latch values and the latch inverse-values, and composing the latch values and the latch inverse-values according to a target decoding value of a decoding unit to output a pre-decoding value; and
at least one decoding unit having the target decoding value for receiving the pre-decoding value, wherein the decoding unit determines whether the pre-decoding value meets decoding conditions of the decoding circuit to decide whether a decoding signal is outputted.

2. The expandable decoding circuit as claimed in claim 1, wherein the raw data comprises a plurality of bits, the latch unit utilizes a plurality of latch elements to latch the bits of the raw data to be the latch values and the latch inverse-values for outputting.

3. The expandable decoding circuit as claimed in claim 1, wherein the decoding unit has a logic circuit structure.

4. The expandable decoding circuit as claimed in claim 3, wherein the decoding unit comprises two NAND gates and an NOR gate.

5. The expandable decoding circuit as claimed in claim 3, wherein the decoding unit comprises three AND gates.

6. The expandable decoding circuit as claimed in claim 1, wherein the decoding unit further comprises a decoding switch for controlling the decoding unit to turn on or off.

7. The expandable decoding circuit as claimed in claim 6, wherein the decoding circuit is located in a system, and the system controls the decoding switch.

8. A decoding method, comprising:
receiving raw data;
generating latch values and latch inverse-values of the raw data;
composing the latch values and the latch inverse-values to form a pre-decoding value according to a target decoding value of at least one decoding circuit, and outputting the pre-decoding value to the corresponding decoding circuit; and
determining whether the pre-decoding value is decoded or not via the decoding circuit, wherein when the pre-decoding value is decoded, the decoding circuit outputs a decoding signal.

9. The decoding method as claimed in claim 8, wherein the decoding circuit further comprises a step of determining whether a decoding switch is turned off or not to decide whether the decoding signal is outputted.

10. The decoding method as claimed in claim 9, wherein the decoding signal is outputted when both the pre-decoding value and a signal of the decoding switch are equal to 1.

11. The decoding method as claimed in claim 9, wherein the decoding signal is not outputted when one bit of the pre-decoding value or the signal of the decoding switch does not equal 1.

12. The decoding method as claimed in claim 8, wherein the decoding unit checks all bits of the pre-decoding value being 1, and outputs the decoding signal.

13. The decoding method as claimed in claim 8, wherein the pre-decoding value is obtained from the latch inverse-value of the raw data when the bit value of the target decoding value is 0.
